(19) United States
(12) Patent Application Publication
(10) Pub. No.: US 2026/0190813 A1
(43) Pub. Date: Jul. 2, 2026

(54) DISPLAY DEVICE

(71) Applicant: LG Display Co., Ltd., Seoul (KR)

(72) Inventor: HwaYoul LEE, Gimpo-si (KR)

(73) Assignee: LG Display Co., Ltd., Seoul (KR)

(21) Appl. No.: 19/425,764

(22) Filed: Dec. 18, 2025

(30) Foreign Application Priority Data
Dec. 30, 2024 (KR) 10-2024-0200827

(51) Int. Cl. H10K 59/80; H10K 59/38; H10K 59/88; H10K 102/00

(52) U.S. Cl. CPC H10K 59/879; H10K 59/38; H10K 59/88; H10K 2102/331

(57) ABSTRACT

A display device is disclosed, and includes a substrate, a plurality of transistors disposed on the substrate, a plurality of light emitting elements which is disposed on the plurality of transistors and includes an anode electrode, a light emitting layer, and a cathode electrode, a plurality of color filters disposed on the plurality of light emitting elements, a plurality of high refractive patterns which is disposed to be spaced apart from each other so as to correspond to each of the plurality of color filters and includes a plurality of first protrusions on an upper surface, an air layer in an area where the plurality of high refractive patterns is spaced apart from each other, and a low refractive layer which is disposed on the plurality of high refractive patterns and the air layer and has a refractive index smaller than that of the plurality of high refractive patterns.

### CROSS-REFERENCE TO RELATED APPLICATIONS

This application claims the priority of Korean Patent Application No. 10-2024-0200827 filed on Dec. 30, 2024, in the Korean Intellectual Property Office, the disclosure of which is incorporated herein by reference.

### BACKGROUND

### Technical Field

The present specification relates to a display device, and more particularly, to a display device with improved light extraction efficiency.

### Description of the Related Art

As it enters the information age, the field of display devices that visually display electrical information signals is rapidly developing, and research is being conducted to improve performances such as thinning, weight reduction, and low power consumption for various display devices.

Representative display devices include a liquid crystal display (LCD), a field emission display (FED), an electro-wetting display (EWD), and an organic light emitting display (OLED), and the like.

An electroluminescent display device represented by an organic light emitting display device is a self-emitting display device and does not require a separate light source unlike a liquid crystal display device. Therefore, the electroluminescent display device can be manufactured to have a light weight and a small thickness. In addition, the electroluminescent display device is advantageous in terms of power consumption because the electroluminescent display device operates at a low voltage. Further, the electroluminescent display device is expected to be utilized in various fields because the electroluminescent display device is excellent in color implementation, response speeds, viewing angles, and contrast ratios (CRs).

### BRIEF SUMMARY

The disclosure presents a display device with a plurality of high refractive patterns, each of which correspond to a respective color filter. A low refractive layer above the high refractive patterns and an air layer adjacent to a side of the high refractive patterns. The high refractive patterns have a higher refractive index than the low refractive layer and the air layer. The high refractive patterns may include a plurality of protrusions to further enhance the refractive effect of the high refractive patterns.

Such a configuration enables improved light extraction efficiency or, in other words, improved light is displayed by the display device. The improved light extraction efficiency enables the display to provide a high-quality image while using less power, as light generated by the display device can more efficiently exit the display device.

Various embodiments of the present disclosure provide a display device with improved light extraction efficiency.

Various embodiments of the present disclosure provide a display device which suppresses light passing through a color filter from being mixed with light passing through another adjacent color filter.

Technical benefits of the present disclosure are not limited to the above-mentioned benefits, and other benefits, which are not mentioned above, can be clearly understood by those skilled in the art from the following descriptions.

According to an aspect of the present disclosure, there is provided a display device. The display device includes a substrate, a plurality of transistors disposed on the substrate, a plurality of light emitting elements which is disposed on the plurality of transistors and includes an anode electrode, a light emitting layer, and a cathode electrode, a plurality of color filters disposed on the plurality of light emitting elements, a plurality of high refractive patterns which is disposed to be spaced apart from each other so as to correspond to each of the plurality of color filters and includes a plurality of first protrusions on an upper surface, an air layer in an area where the plurality of high refractive patterns is spaced apart from each other, and a low refractive layer which is disposed on the plurality of high refractive patterns and the air layer and has a refractive index smaller than that of the plurality of high refractive patterns.

According to another aspect of the present disclosure, there is provided a display device. The display device includes: a substrate; a plurality of light emitting elements which is disposed on the substrate and includes an anode electrode, a light emitting layer, and a cathode electrode; a plurality of color filters disposed on the plurality of light emitting elements; a plurality of high refractive patterns which correspond to each of the plurality of color filters, are disposed to be spaced apart from each other with an air layer interposed therebetween, and include a plurality of first protrusions disposed in a sub-wavelength grating structure on each upper surface thereof, and a plurality of second protrusions disposed on each side in a smaller number per unit area than the plurality of first protrusions; and a low refractive layer covering the high refractive pattern and the air layer, wherein a refractive index of the high refractive pattern is greater than a refractive index of the air layer and the low refractive layer.

Other detailed matters of the embodiments are included in the detailed description and the drawings.

According to the present disclosure, a color mixture between adjacent sub pixels is suppressed to implement a higher quality image.

According to the present disclosure, it is possible to improve the light extraction efficiency from the light emitting element.

According to the present disclosure, it is possible to implement a high-quality image with lower power by improving light extraction efficiency.

The effects according to the present specification are not limited to the contents exemplified above, and more various effects are included in the present disclosure.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a plan view of a display device according to an exemplary embodiment of the present disclosure.

FIG. 2 is a cross-sectional view illustrating an example of a cross-sectional structure of a pixel in the display device according to the embodiment of the present specification.

FIGS. 3A to 3E are process diagrams for explaining a method of manufacturing a display device according to an exemplary embodiment of the present disclosure.

FIG. 4 is a cross-sectional view illustrating an example of a cross-sectional structure of a pixel in a display device according to another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,”. “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

The phrase “A filled in B” does not imply that A is exclusively contained within B to the exclusion of other materials. Instead, it is intended to encompass a broad range of conditions, including but not limited to “partially filled in,” “substantially filled in,” “completely filled in,” and “exclusively filled in.” Similarly, the phrase “B filled with A” does not suggest that B is exclusively filled with A, excluding other materials. Rather, it covers various degrees of filling, such as “partially filled with,” “substantially filled with,” “completely filled with,” and “exclusively filled with.”

The features of various embodiments of the present disclosure can be partially or entirely adhered to or combined with each other and can be interlocked and operated in technically various ways, and the embodiments can be carried out independently of or in association with each other.

Hereinafter, exemplary embodiments of the present disclosure will be described in detail with reference to accompanying drawings.

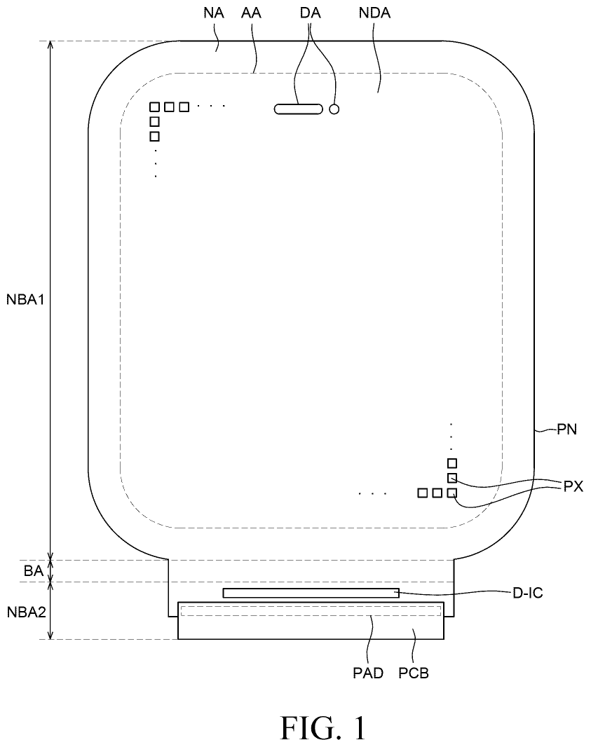

FIG. 1 is a plan view of a display device according to an exemplary embodiment of the present disclosure.

Referring to FIG. 1, a display device 100 includes a display panel PN, a pad part PAD, a gate driver, a driving integrated circuit D-IC, and a printed circuit board PCB.

In the display panel PN, an active area AA and a non-active area NA enclosing the active area AA may be defined. The active area AA is an area in which an image is actually displayed in the display device 100, and a light emitting element to be described later and various driving elements for driving the light emitting element may be disposed in the active area AA. The non-active area NA is an area where no image is displayed and may be defined as an area surrounding the active area AA. Various components for driving the plurality of pixels PX disposed in the active area AA may be disposed in the non-active area NA.

Referring to FIG. 1, the active area AA may include a non-optical area NDA and one or more optical areas DA. One or more optical areas DA may be areas overlapping one or more optical electronic devices. Light enters the front surface (a viewing surface) of the display panel PN, passes through the display panel PN through the optical area DA, and may be transmitted to one or more optical electronic devices positioned below the display panel PN (opposite to the viewing surface). The one or more optical electronic devices may be devices that receive light transmitted through the display panel PN and perform a predetermined function according to the received light. For example, the optical electronic device may include at least one of a camera or a proximity sensor.

One or more optical areas DA must have a transmittance at a certain level or higher, and the non-optical areas NDA may not have light transmittance or have low transmittance at less than a certain level. For example, one or more optical areas DA and non-optical areas NDA may have different resolutions, sub-pixel arrangement structures, number of sub-pixels per unit area, electrode structures, line structures, electrode arrangement structures, or line arrangement structures. For example, the number of sub pixels per unit area in one or more optical areas DA may be smaller than the number of sub pixels per unit area in the non-optical area NDA.

Referring to FIG. 1, the display panel PN may include a first non-bending area NBA1, a bending area BA that is bent by extending from one side of the first non-bending area NBA1 and one side of the active area AA, and a second non-bending area NBA2 that extends from one side of the bending area BA and includes the non-active area NA. The first non-bending area NBA1 corresponds to the active area AA in which the plurality of pixels PX is disposed, and is an area that maintains a flat state. The second non-bending area NBA2 is an area facing the first non-bending area NBA1 and is an area in which circuit elements are disposed, such as the driving integrated circuit D-IC and the printed circuit board PCB connected to the pad part PAD, and maintain a flat state.

The bending area BA is an area that maintains a bent state. Meanwhile, a notch formed by cutting both edges of the display panel PN in the bending area BA of the display panel PN may be disposed. Therefore, the area of the display panel PN disposed in the bending area BA is relatively reduced so that the stress to be applied to the display panel PN may be reduced.

The pad part PAD is disposed in the second non-bending area NBA2. The pad part PAD may be electrically connected to the printed circuit board PCB to receive a data driving signal or the like or exchange a touch signal with an external power source.

The driving integrated circuit D-IC may be disposed in the second non-bending area NBA2. The driving integrated circuit D-IC may provide a data signal to the plurality of pixels PX. For example, the driving integrated circuit D-IC samples and latches the data signal supplied from the timing controller in response to the data timing control signal supplied from the timing controller to convert the data signal into a gamma reference voltage and output the converted gamma reference voltage. The driving integrated circuit D-IC may output a data signal through a plurality of data lines.

As the bending area BA is bent, the driving integrated circuit D-IC and the printed circuit board PCB connected to the pad part PAD move to the rear surface of the display panel PN and overlap the first non-bending area NBA1. As the bending area BA is bent, the size of the non-active area NA visible from the top of the display panel PN is reduced so that a narrow bezel may be implemented.

In the first non-bending area NBA1, a gate driver may be disposed in the non-active area NA. The gate driver is disposed on the side surface of the active area AA to output a gate signal and an emission control signal under the control of a timing controller to select a pixel PX in which a data voltage is charged through wiring such as gate wiring and emission control signal wiring and adjust the emission timing. The gate driver may be directly formed on the display panel PN in a gate-driver in panel (GIP) manner, but is not limited thereto.

A plurality of data lines connected to the driving integrated circuit D-IC and extending to the bending area BA and the first non-bending area NBA1 may be disposed. The plurality of data lines may transmit a signal applied to the driving integrated circuit D-IC to the pixel PX disposed in the active area AA.

A plurality of gate link lines which connects the driving integrated circuit D-IC and the gate driver may be disposed in the first non-bending area NBA1. The gate link line may transmit external power coming from the pad part PAD to the gate driver disposed in the first non-bending area NBA1.

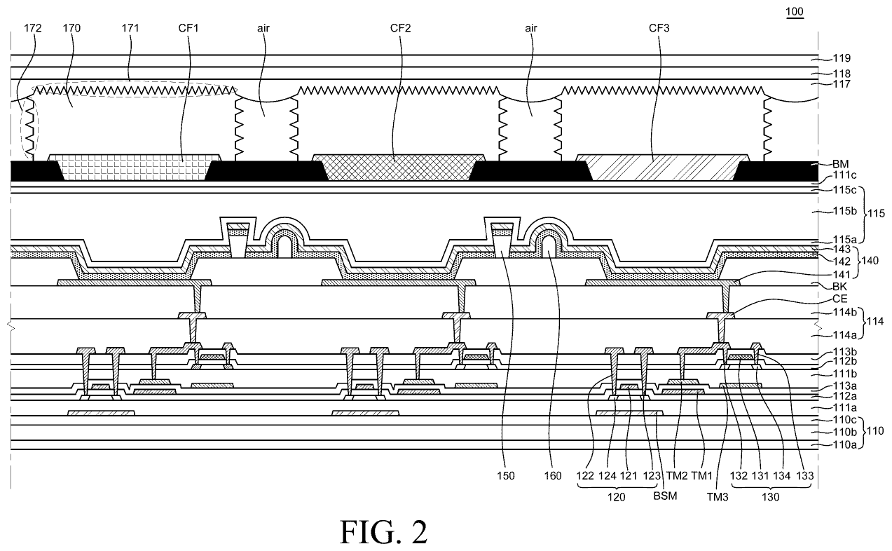

FIG. 2 is a cross-sectional view illustrating an example of a cross-sectional structure of a pixel in the display device according to the embodiment of the present specification.

Referring to FIG. 2, a display device 100 according to an exemplary embodiment of the present disclosure may include a substrate 110, buffer layers 111, 111a, and 111b, gate insulating layers 112a and 112b, interlayer insulating layers 113a, 113b, and 113c, a plurality of transistors 120 and 130, a planarization layer 114, a light emitting element 140, an encapsulation member 115, a high refractive pattern 170, a low refractive layer 117, an adhesive layer 118, and a cover member 119.

The substrate 110 is a component for supporting various components included in the display device 100 and may be made of an insulating material. The substrate 110 may include a first substrate 110a, a second substrate 110c, and an insulating film 110b disposed between the first substrate 110a and the second substrate 110c, but is not limited thereto.

A light shielding layer BSM may be disposed on the substrate 110. The light shielding layer BSM is disposed below the plurality of transistors 120 and 130 to minimize damage to the plurality of transistors 120 and 130 caused by charges trapped in the substrate 110.

The first buffer layer 111a may be disposed on the light shielding layer BSM. The first buffer layer 111a may reduce penetration of moisture or impurities through the substrate 110.

The first gate insulating layer 112a may be disposed on the first active layer 124. The first gate insulating layer 112a may be formed of a single layer of silicon oxide (SiOx) or silicon nitride (SiNx) or a double layer thereof, but is not limited thereto.

The first gate electrode 121 of the first transistor 120 may be disposed on the first gate insulating layer 112a. The first gate electrode 121 may be disposed on the first gate insulating layer 112a so as to overlap the first active layer 124.

A first metal layer TM1 may be disposed on the first gate insulating layer 112a. In this case, the first metal layers TM1 may be disposed to be spaced apart from each other on the same layer as the first gate electrode 121 of the first transistor 120. The first metal layer TM1 may be formed of the same material as the first gate electrode 121.

A first interlayer insulating layer 113a may be disposed on the first gate electrode 121 and the first metal layer TM1. The first interlayer insulating layer 113a may be disposed to cover the first gate electrode 121 and the first metal layer TM1.

A second metal layer TM2 and a third metal layer TM3 may be disposed on the first interlayer insulating layer 113a. The second metal layer TM2 may be disposed to overlap the first metal layer TM1 to implement a capacitor.

The third metal layer TM3 may be disposed to overlap the second active layer 134 of the second transistor 130. Therefore, the third metal layer TM3 may serve to protect the second active layer 134 of the second transistor 130.

A second buffer layer 111b may be disposed on the second metal layer TM2 and the third metal layer TM3. The second buffer layer 111b may be disposed to cover the second metal layer TM2 and the third metal layer TM3. Further, the second buffer layer 111b may planarize lower components.

The second active layer 134 of the second transistor 130 may be disposed on the second buffer layer 111b.

The second gate insulating layer 112b may be disposed on the second active layer 134. The second gate insulating layer 112b may insulate the second active layer 134 of the second transistor 130 from the second gate electrode 131.

The second gate electrode 131 of the second transistor 130 may be disposed on the second gate insulating layer 112b. The second gate electrode 131 may be disposed on the second gate insulating layer 112b so as to overlap the second active layer 134.

A second interlayer insulating layer 113b may be disposed on the second gate electrode 131. The second interlayer insulating layer 113b may be disposed to cover the second gate electrode 131 of the second transistor 130.

The first source electrode 122 and the first drain electrode 123 of the first transistor 120 may be disposed on the second interlayer insulating layer 113b. Further, the second source electrode 132 and the second drain electrode 133 of the second transistor 130 may be disposed on the second interlayer insulating layer 113b. The first source electrode 122, the first drain electrode 123, the second source electrode 132, and the second drain electrode 133 may be disposed on the same layer. Further, the first source electrode 122, the first drain electrode 123, the second source electrode 132, and the second drain electrode 133 may be formed of the same material. Further, the first source electrode 122, the first drain electrode 123, the second source electrode 132, and the second drain electrode 133 may be formed by the same process.

The first source electrode 122 and the first drain electrode 123 of the first transistor 120 may be connected to one side and the other side of the first active layer 124 through contact holes provided in the second interlayer insulating layer 113b, the second gate insulating layer 112b, the second buffer layer 111b, the first interlayer insulating layer 113a, and the first gate insulating layer 112a, respectively.

The second source electrode 132 and the second drain electrode 133 of the second transistor 130 may be connected to one side and the other side of the second active layer 134 through contact holes provided in the second interlayer insulating layer 113b and the second gate insulating layer 112b, respectively. Further, the second source electrode 132 extends to one side to be connected to the second metal layer TM2 through contact holes provided in the second interlayer insulating layer 113b, the second gate insulating layer 112b, and the second buffer layer 111b. However, the present disclosure is not limited thereto, and the connection relationship may be changed according to the pixel driving circuit.

A planarization layer 114 may be disposed on the first source electrode 122, the first drain electrode 123, the second source electrode 132, and the second drain electrode 133. The planarization layer 114 may be disposed on the first transistor 120 and the second transistor 130 and protect the first transistor 120 and the second transistor 130. Further, the planarization layer 114 may planarize upper portions of the first transistor 120 and the second transistor 130. The planarization layer 114 may be an organic film such as polyimide or acrylic resin, but is not limited thereto.

The planarization layer 114 may include a plurality of layers. For example, the planarization layer 114 may include a first planarization layer 114a and a second planarization layer 114b.

A first planarization layer 114a may be disposed on the first source electrode 122, the first drain electrode 123, the second source electrode 132, and the second drain electrode 133. The first planarization layer 114a may planarize upper portions of the first source electrode 122, the first drain electrode 123, the second source electrode 132, and the second drain electrode 133.

The connection electrode CE may be disposed on the first planarization layer 114a. The connection electrode CE may be connected to the second source electrode 132 of the second transistor 130 through a contact hole provided in the first planarization layer 114a. The connection electrode CE may electrically connect the plurality of light emitting elements 140 to the second source electrode 132 of the second transistor 130.

The second planarization layer 114b may be disposed on the connection electrode CE. The second planarization layer 114b is disposed to cover the connection electrode CE to planarize the upper portion of the connection electrode CE.

An anode electrode 141, among a plurality of light emitting elements 140, may be disposed on the second planarization layer 114b. The anode electrode 141 may be formed in a multilayer structure including a transparent conductive film and an opaque conductive film having high reflection efficiency. The transparent conductive film may be formed of indium-tin-oxide (ITO) or indium-zinc-oxide (IZO), and the opaque conductive film may be formed of a single layer or a multi-layered structure including aluminum (Al), silver (Ag), copper (Cu), lead (Pb), molybdenum (Mo), titanium (Ti), or an alloy thereof.

The anode electrode 141 may be connected to the connection electrode CE through a contact hole provided in the second planarization layer 114b. Therefore, the anode electrode 141 may be electrically connected to the second source electrode 132 of the second transistor 130 through the connection electrode CE.

A bank BK may be disposed on the second planarization layer 114b. The bank BK may be disposed between a plurality of anode electrodes 141. Further, the bank BK may be disposed to cover an end of the anode electrode 141. Accordingly, a part of the anode electrode 141 may be exposed by the bank BK. Further, an emission area may be defined by the exposed anode electrode 141.

The spacer 160 may be disposed on the bank BK. The spacer 160 may be formed of the same material as the bank BK. The spacer 160 may perform a function of preventing the damage of the light emitting element 140 which may be caused by a fine metal mask (FMM) used when the light emitting layer 142 is patterned.

The partition wall 150 may be disposed on the bank BK. The partition wall 150 is disposed on the bank BK to disconnect the light emitting layer 142 and the cathode electrode 143. The partition wall 150 may have an inverted taper shape to efficiently disconnect the light emitting layer 142 and the cathode electrode 143, but is not limited thereto.

The light emitting layer 142 may be disposed on the anode electrode 141 exposed by the bank BK. The emission layer 142 may emit light by receiving a voltage from the anode electrode 141 and the cathode electrode 143. The emission layer 142 may extend to the top surface of the bank BK from the anode electrode 141 exposed by the bank BK. However, the light emitting layer 142 may be disconnected on the bank BK by the partition wall 150 disposed on the bank BK.

The cathode electrode 143 may be disposed on the emission layer 142. The cathode electrode 143 may be connected to a separate power line to apply a voltage to the light emitting layer 142. The cathode electrode 143 may be disconnected by the partition wall 150 on the bank BK.

The encapsulation member 115 may be disposed on the plurality of light emitting elements 140. The encapsulation member 115 may prevent damage to the light emitting element 140 due to moisture and impact from the outside. The encapsulation member 115 may have a multilayer structure. For example, the encapsulation member 115 may include a first encapsulation layer 115a, a second encapsulation layer 115b, and a third encapsulation layer 115c sequentially stacked. For example, the first encapsulation layer 115a and the third encapsulation layer 115c may be inorganic encapsulation layers including an inorganic insulating material, and the second encapsulation layer 115b may be an organic encapsulation layer including an organic insulating material. Accordingly, the light emitting element 140 of the display device 100 may be more effectively prevented from being damaged by external moisture and impact.

The third buffer layer 111c may be disposed on the encapsulation member 115.

A black matrix BM may be disposed on the third buffer layer 111c. The black matrix BM may be disposed on the third buffer layer 111c so as to be positioned between the plurality of color filters CF1, CF2, and CF3. The black matrix BM may partition each of the plurality of color filters CF1, CF2, and CF3. Specifically, the black matrix BM may include an opening corresponding to an emission area of the light emitting element 140. The black matrix BM may be disposed to overlap the bank BK. Accordingly, color mixture between sub-pixels may be minimized. Further, the black matrix BM absorbs external light. Accordingly, deterioration in visibility and contrast ratio of the display device 100 due to external light may be minimized.

The plurality of color filters CF1, CF2, and CF3 may be disposed on the third buffer layer 111c so as to correspond to an emission area of the light emitting element 140 disposed therebelow. The plurality of color filters CF1, CF2, and CF3 may be disposed at the openings of the black matrix BM, respectively. The color filters CF1, CF2, and CF3 may be disposed to cover the end of the black matrix BM. Therefore, the widths of the color filters CF1, CF2, and CF3 may be larger than the widths of the openings of the bank BK. The widths of the color filters CF1, CF2, and CF3 may be larger than the width of the emission area of the light emitting element 140. Therefore, the light conversion efficiency of the color filters CF1, CF2, and CF3 may be further improved.

Each of the color filters CF1, CF2, and CF3 is not in contact with each other on the black matrix BM, but may be independently disposed so as to correspond to each emission area. Each of the color filters CF1, CF2, and CF3 may correspond to a color of each emission area corresponding thereto. That is, the plurality of color filters CF1, CF2, and CF3 may include a first color filter CF1, a second color filter CF2, and a third color filter CF3 having different colors.

For example, the first color filter CF1 may be a red color filter that transmits red light. The second color filter CF2 may be a green color filter that transmits green light. Further, the third color filter CF3 may be a blue color filter that transmits blue light, but is not limited thereto.

A plurality of high refractive patterns 170 including a plurality of first protrusions 171 are disposed on the top surfaces of the plurality of color filters CF1, CF2, and CF3. Each of the plurality of high refractive patterns 170 is disposed to be spaced apart from each other corresponding to each of the plurality of color filters CF1, CF2, and CF3. Accordingly, the high refractive pattern 170 may be disposed to overlap the emission area of the light emitting device 140. The distance between the high refractive patterns 170 may be 1 μm or less. The high refractive pattern 170 may serve to refract light emitted from the light emitting element 140 to the upper surface of the substrate 110.

A width of the high refractive pattern 170 may be larger than a width of the color filters CF1, CF2, and CF3. Therefore, the high refractive pattern 170 may be disposed to completely cover the color filters CF1, CF2, and CF3. The end of the high refractive pattern 170 may be disposed on the upper surface of the black matrix BM.

An air layer is disposed between the plurality of high refractive patterns 170. The plurality of high refractive patterns 170 are spaced apart from each other with an air layer therebetween. The air layer air may be disposed to overlap the bank BK and the black matrix BM. Accordingly, the air layer may not overlap the emission area of the light emitting element 140. The upper portion of the air layer air may have a concave shape toward the substrate 110, but is not limited thereto.

The plurality of first protrusions 171 may be disposed in a sub-wavelength grating structure on the upper surface of the high refractive pattern 170. Specifically, the periods of the plurality of first protrusions 171 may be arranged to have periods equal to or less than the optical wavelength emitted from the light emitting element 140 on the top surface of the high refractive pattern 170. For example, a period of the plurality of first protrusions 171 may be 200 nm to 400 nm. A height of each of the plurality of first protrusions 171 may be 200 nm to 600 nm, but is not limited thereto.

Each of the plurality of first protrusions 171 may have a shape whose width becomes narrower toward the top. For example, each of the plurality of first protrusions 171 may have a conical shape. In this case, when the widths of the upper and lower portions of the plurality of first protrusions 171 are different from each other, the period of the plurality of first protrusions 171 may be designed based on the lower surface. For example, when the first protrusion 171 has a conical shape, a lower surface of the first protrusion 171 may be disposed to form a sub-wavelength grating structure on the upper surface of the high refractive pattern 170.

The high refractive pattern 170 may further include a plurality of second protrusions 172 disposed on a side surface thereof. The plurality of second protrusions 172 may have the same shape as the plurality of first protrusions 171, but is not limited thereto. For example, the plurality of second protrusions 172 may have a different shape from the plurality of first protrusions 171. When the plurality of second protrusions 172 is disposed on the side surface of the high refractive pattern 170, a distance between the high refractive patterns 170 may mean a distance between a plurality of adjacent second protrusions 172.

A loading density of the plurality of first protrusions 171, or in other words, the packing density may be greater than that of the plurality of second protrusions 172. In this case, the loading density means the number of protrusions disposed per the same unit area. Accordingly, the number of the plurality of first protrusions 171 disposed per unit area on the upper surface of the high refractive pattern 170 may be greater than the number of the plurality of second protrusions 172 disposed per the same unit area on the side surface of the high refractive pattern 170.

In addition, a period of the plurality of first protrusions 171 may be smaller than a period of the plurality of second protrusions 172, but is not limited thereto.

An air layer may be filled between a plurality of second protrusions 172. For example, the air layer may fill a space between a plurality of second protrusions 172 facing each other in the high refractive pattern 170 adjacent to each other. Further, the air layer may fill an area formed between a plurality of second protrusions 172 disposed on the same side surface of any one high refractive pattern 170.

The refractive index of the high refractive pattern 170 may be greater than that of the air layer and the low refractive layer 117. For example, the refractive index of the high refractive pattern 170 may be 1.6 or higher, but is not limited thereto. The high refractive pattern 170 may be formed of, for example, photoresist (PR), acryl resin or triazine containing fluorine, but is not limited thereto. Further, the high refractive pattern 170 may further include inorganic particles such as titanium dioxide (TiO₂) or zirconium dioxide (ZrO₂) to improve the refractive index. The plurality of first protrusions 171 and the plurality of second protrusions 172 may be formed of the same material as the high refractive pattern 170.

A low refractive layer 117 having a refractive index smaller than that of the high refractive pattern 170 is disposed on the plurality of high refractive patterns 170 and the air layer. In addition, the refractive index of the low refractive layer 117 may be greater than that of the air layer. The low refractive layer 117 may be formed of an organic material having a refractive index smaller than that of the high refractive pattern 170, and does not specifically limit the type thereof. Accordingly, the low refractive layer 117 may fill a space between the plurality of first protrusions 171 disposed on the upper surface of the high refractive pattern 170. Further, an interface where the low refractive layer 117 and the air layer are in contact with each other may have a concave shape toward the substrate 110.

An adhesive layer 118 may be disposed on the low refractive layer 117. The adhesive layer 118 may have a refractive index smaller than that of the low refractive layer 117. In addition, the adhesive layer 118 may have a refractive index larger than that of the air layer. The adhesive layer 118 may include pressure sensitive adhesive (PSA), optical clear adhesive (OCA), or optical clear resin (OCR), but is not limited thereto.

A cover member 119 may be disposed on the adhesive layer 118. The cover member 119 may protect the display device 100 from external shocks or scratches. The cover member 119 may be formed of a material having excellent impact resistance and light transmittance. For example, the cover member 119 may be made of tempered glass or transparent plastic. For example, the transparent plastic may be selected from polymethyl methacrylate (PMMA), polycarbonate (PC), cycloolefin polymer, polyethylene terephthalate (PET), and polyimide (PI), but is not limited thereto.

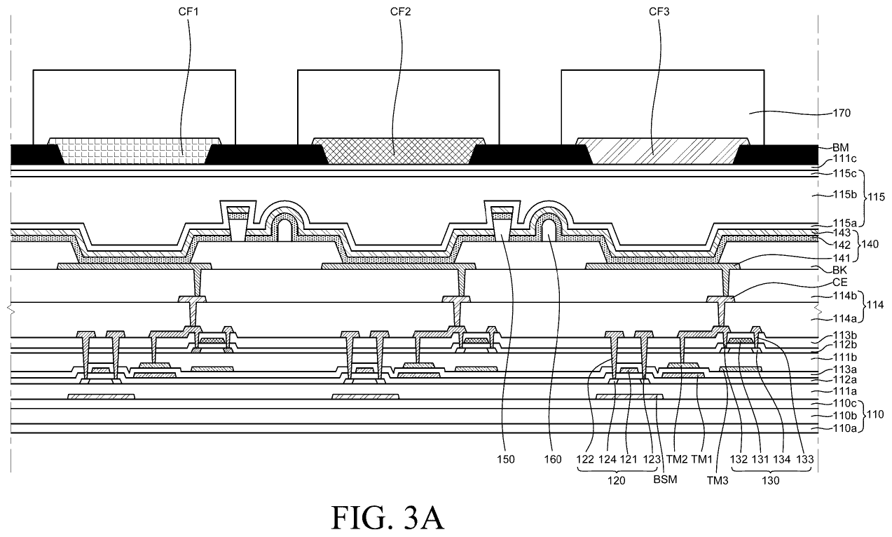

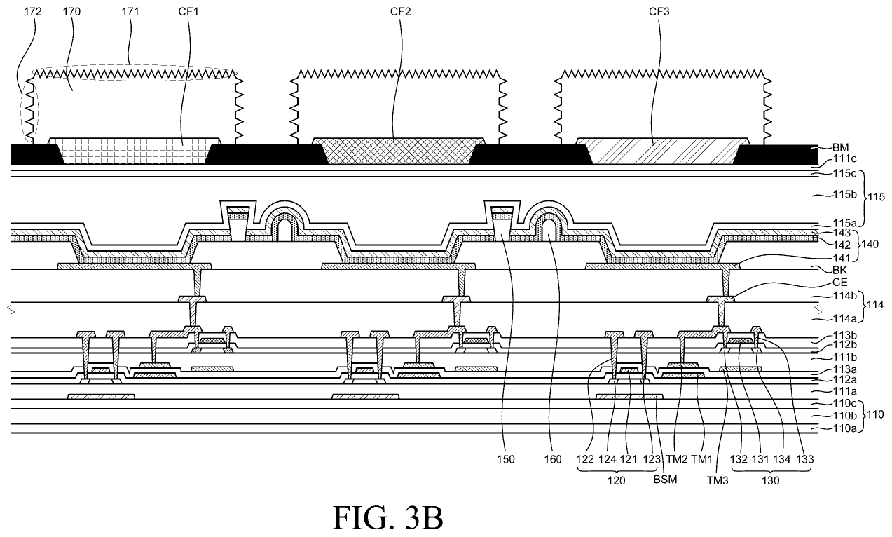

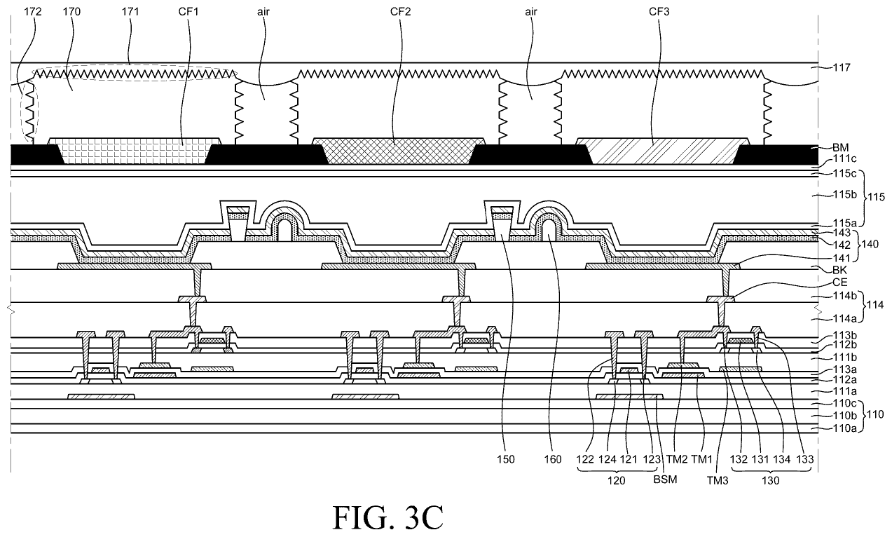

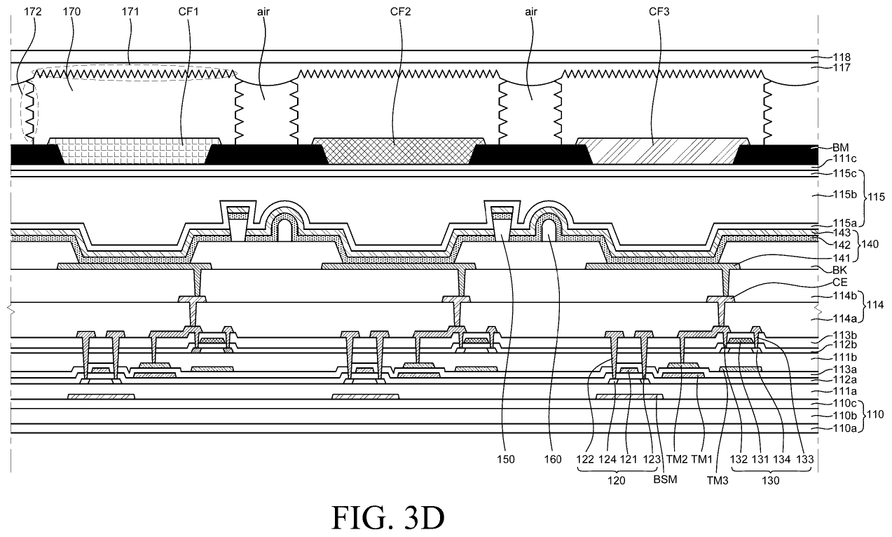

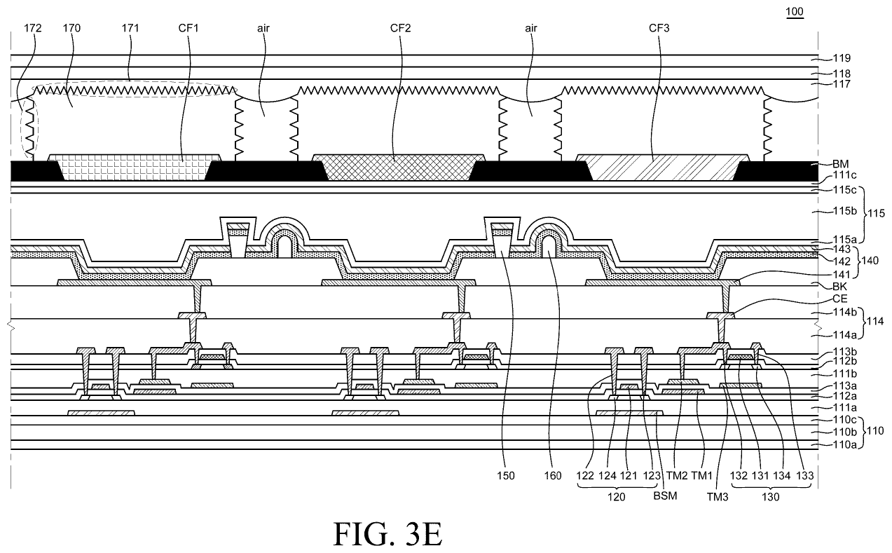

Hereinafter, a method of manufacturing a display device according to an exemplary embodiment of the present disclosure will be described with reference to FIGS. 3A to 3E.

FIGS. 3A to 3E are process diagrams for explaining a method of manufacturing a display device according to an exemplary embodiment of the present disclosure.

Specifically, FIGS. 3A to 3E are process diagrams for explaining a method of forming the high refractive pattern 170 on the color filters CF1, CF2, and CF3. A description of a manufacturing method from the substrate 110 to the color filters CF1, CF2, and CF3 will be omitted.

Referring to FIG. 3A, a material for forming the high refractive pattern 170 may be applied on the color filters CF1, CF2, and CF3 and the black matrix BM. Further, exposure and development may be performed using a photo mask on a material for forming the high refractive pattern 170. Accordingly, a material disposed in a part of the area overlapping the black matrix BM is removed, so that a plurality of high refractive patterns 170 may be formed.

Referring to FIG. 3B, oxygen (O₂) plasma may be irradiated to the upper surface and the side surface of the formed high refractive pattern 170 to form a plurality of first protrusions 171 and a plurality of second protrusions 172. In this case, based on the same unit area, the loading density of the first protrusion 171 formed on the upper surface of the high refractive pattern 170 may be formed to be greater than the loading density of the second protrusion 172 formed on the side surface. Further, the second protrusion 172 may be formed so that the maximum distance between the side surfaces of the high refractive patterns 170 adjacent to each other is 1 μm or less.

Referring to FIG. 3C, the low refractive layer 117 may be formed by coating and curing an organic material for forming the low refractive layer 117 on the high refractive pattern 170. In this case, the organic material may be a material having a refractive index smaller than that of a material for forming the high refractive pattern 170. As the organic material is applied to the upper surface of the high refractive pattern 170, the material for forming the low refractive layer 117 may be filled between the plurality of first protrusions 171 disposed on the upper surface of the high refractive pattern 170. On the other hand, since the area in which the plurality of high refractive patterns 170 are spaced apart is a narrow space of 1 μm or less, the organic material may not fill between the spaced areas. Specifically, after coating an organic material for forming the low refractive layer 117 on the high refractive pattern 170, the organic material may be cured before the organic material is filled between the spaced areas of the high refractive pattern 170. Therefore, an organic material for forming the low refractive layer 117 is not filled in an area where the high refractive pattern 170 is spaced apart from each other, and an air layer may be formed.

Referring to FIGS. 3D and 3E together, after coating an adhesive material for forming the adhesive layer 118 on the low refractive layer 117, the cover member 119 may be stacked. Next, the display device 100 may be manufactured by curing the adhesive material.

A display device 100 according to an exemplary embodiment of the present disclosure includes a high refractive pattern 170 overlapping an emission area and a low refractive layer 117 disposed above the high refractive pattern 170. Further, a plurality of first protrusions 171 are included on the upper surface of the high refractive pattern 170. Accordingly, the reflection of light at the interface between the high refractive pattern 170 and the low refractive layer 117 may be suppressed by the plurality of first protrusions 171. Accordingly, an extraction amount of light emitted from the light emitting element 140 may increase.

Further, in the display device 100 according to the exemplary embodiment of the present disclosure, the plurality of high refractive patterns 170 is spaced apart from each other with an air layer therebetween. At this time, since the difference in refractive index between the high refractive pattern 170 and the air layer is large, the amount of light reflected at the interface may increase. Accordingly, light emitted from the light emitting element 140 may not pass through the side surface of the high refractive pattern 170, and may be reflected from the side surface of the high refractive pattern 170 and the interface of the air layer. The path of the reflected light may be changed in the upward direction of the substrate 110 again. Accordingly, it is possible to suppress the loss of light emitted from the light emitting element 140 to the side through the color filters CF1, CF2, and CF3. In addition, by changing the path of light lost to the side, the amount of light extracted to the upper portion of the substrate 110 may be further increased.

In the display device 100 according to the exemplary embodiment of the present disclosure, the plurality of first protrusions 171 may be disposed in a sub-wavelength grating structure of the high refractive pattern 170. As described above, when the plurality of first protrusions 171 are disposed in a sub-wavelength grating structure, light may be prevented from being diffracted. As described above, when the diffracted light disappears, the effective refractive index in the grating structure may be determined according to the fill factor of the grating structure by the effective medium theory. In this case, when the first protrusion 171 has a shape whose width becomes narrower toward the top of the substrate 110, the filling ratio of the first protrusion 171 of the high refractive pattern 170 gradually decreases toward the top. As the filling ratio of the first protrusion 171 gradually decreases, the effective refractive index may also gradually change upward. As described above, as the effective refractive index gradually changes toward the upper portion of the substrate 110, reflection of light generated at the interface between the high refractive pattern 170 and the low refractive layer 117 may be more suppressed. Accordingly, a greater amount of light may be emitted toward the top of the substrate 110.

As described above, in the display device 100 according to the exemplary embodiment of the present disclosure, the amount of light emitted to the upper portion of the substrate 110 may increase. Further, as the light extraction efficiency increases, the display device 100 according to the exemplary embodiment of the present disclosure may provide a high-quality image with a lower power.

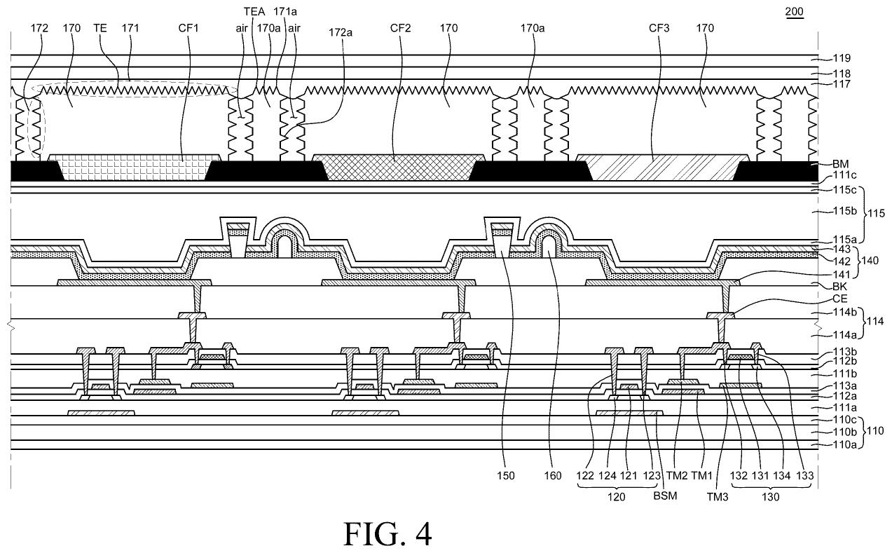

FIG. 4 is a cross-sectional view illustrating an example of a cross-sectional structure of a pixel in a display device according to another exemplary embodiment of the present disclosure.

A display device 200 of FIG. 4 has the substantially same configurations as the display device 100 of FIGS. 1 to 3, except for the dummy pattern 170a, so that a redundant description will be omitted.

The display device 200 according to another exemplary embodiment of the present disclosure may further include a plurality of dummy patterns 170a disposed between a plurality of high refractive patterns 170. The dummy pattern 170a may serve to more easily form an air layer between the plurality of high refractive patterns 170.

The plurality of dummy patterns 170a may be disposed on the same layer as the plurality of high refractive patterns 170. Each of the plurality of dummy patterns 170a may be disposed to be spaced apart from the high refractive pattern 170 between two adjacent high refractive patterns 170. In this case, a distance between the high refractive pattern 170 and the dummy pattern 170a may be 1 μm or less.

An air layer may be formed between the high refractive pattern 170 and the dummy pattern 170a. The air layer may be formed when the low refractive layer 117 is covered on the upper portion of the empty space where the high refractive pattern 170 and the dummy pattern 170a are spaced apart from each other.

For example, the dummy pattern 170a may be disposed on the black matrix BM. Therefore, the dummy pattern 170a may be disposed not to overlap the plurality of color filters CF1, CF2, and CF3. As another example, the dummy pattern 170a may be disposed between each sub pixel SP.

The dummy pattern 170a may include the same material as the high refractive pattern 170. For example, the dummy pattern 170a may be formed of photoresist, PR, acryl resin, or triazine containing fluorine, but is not limited thereto.

In addition, the dummy pattern 170a may be formed by the same process as the high refractive pattern 170. Therefore, although the dummy pattern 170a has a different size from the high refractive pattern 170, the dummy pattern 170a may have the same shape. For example, the dummy pattern 170a may include a plurality of third protrusions 171a disposed on an upper surface thereof. A top edge TE of the plurality of third protrusions 171a may be coplanar with a top edge TEA of the plurality of first protrusions 171. Further, the dummy pattern 170a may further include a plurality of fourth protrusions 172a disposed on the side surface. In this case, the plurality of third protrusions 171a corresponds to the plurality of first protrusions 171 of the high refractive pattern 170, and the plurality of fourth protrusions 172a corresponds to the plurality of second protrusions 172 of the high refractive pattern 170, so that a redundant description will be omitted.

As such, the dummy pattern 170a may be formed through the same process as that of the high refractive pattern 170. Accordingly, the dummy pattern 170a may be formed between the high refractive patterns 170 without a separate additional process.

The display device 200 according to another exemplary embodiment of the present disclosure includes the high refractive pattern 170 and the dummy pattern 170a disposed between the high refractive pattern 170 to reduce the width of the empty space formed on the side surface of the high refractive pattern 170. Accordingly, when a material for forming the low refractive layer 117 is applied on the high refractive pattern 170, it is possible to more easily prevent the material for forming the low refractive layer 117 from penetrating into an empty space formed on the side surface of the high refractive pattern 170. Accordingly, an air layer may be more easily formed on the side surface of the high refractive pattern 170.

Accordingly, in the display device 200 according to another exemplary embodiment of the present disclosure, the dummy pattern 170a is further included between the high refractive patterns 170, so that the width of the high refractive pattern 170 may be relatively reduced. Accordingly, an area in which the high refractive pattern 170 overlaps the black matrix BM may be reduced. Accordingly, some light emitted from the light emitting element 140 and directed to the high refractive pattern 170 may be suppressed from being absorbed by the black matrix BM. Accordingly, the amount of light emitted from the light emitting element 140 and reaching the side surface of the high refractive pattern 170 may be further increased. Accordingly, the amount of light refracted above the substrate 110 due to the difference in refractive index between the high refractive pattern 170 and the air on the side surface of the high refractive pattern 170 may also be further increased.

Further, in the display device 200 according to another exemplary embodiment of the present disclosure, the width of the high refractive pattern 170 is reduced so that when light emitted from the light emitting element 140 enters the air layer through the side surface of the high refractive pattern 170, the display device 200 may have a relatively higher angle of incidence. Specifically, as the width of the high refractive pattern 170 decreases, the area overlapping the black matrix BM also decreases, so that the blind spot on the side of the high refractive pattern 170 caused by the black matrix BM may decrease. Accordingly, the amount of light incident at a higher angle of incidence on the side surface of the high refractive pattern 170 may increase. Further, as the amount of light incident on the side surface of the high refractive pattern 170 at an incident angle of a higher angle than a critical angle increases, the amount of light refracted toward the top of the substrate 110 may also increase. Accordingly, the amount of light lost to the side surface of the high refractive pattern 170 may be reduced. Further, the display device 200 according to another exemplary embodiment of the present disclosure may further suppress the reflection of light at the interface between the high refractive pattern 170 and the low refractive layer 117. Accordingly, an extraction amount of light emitted from the light emitting element 140 may be further increased.

In the display device 200 according to another exemplary embodiment of the present disclosure, the amount of light reflected from the side surface of the high refractive pattern 170 may be further increased due to a difference in refractive index between the high refractive pattern 170 and the air layer. Accordingly, it is possible to further suppress the loss of light emitted from the light emitting element 140 to the side through the color filters CF1, CF2, and CF3. In addition, by changing the path of light lost to the side, the amount of light extracted to the upper portion of the substrate 110 may be further increased.

In the display device 200 according to another exemplary embodiment of the present disclosure, as the effective refractive index gradually changes toward the top of the substrate 110, reflection of light generated at an interface between the high refractive pattern 170 and the low refractive layer 117 may be more suppressed. Accordingly, a greater amount of light may be emitted toward the top of the substrate 110. As described above, in the display device 200 according to another exemplary embodiment of the present disclosure, the amount of light emitted to the upper portion of the substrate 110 may increase. Further, as the light extraction efficiency increases, the display device 200 according to another exemplary embodiment of the present disclosure may provide a high-quality image with a lower power.

The exemplary embodiments of the present disclosure can also be described as follows.

According to an aspect of the present disclosure, there is provided a display device. The display device includes a substrate, a plurality of transistors disposed on the substrate, a plurality of light emitting elements which is disposed on the plurality of transistors and includes an anode electrode, a light emitting layer, and a cathode electrode, a plurality of color filters disposed on the plurality of light emitting elements, a plurality of high refractive patterns which is disposed to be spaced apart from each other to correspond to each of the plurality of color filters and includes a plurality of first protrusions on an upper surface, an air layer in an area where the plurality of high refractive patterns is spaced apart from each other, and a low refractive layer which is disposed on the plurality of high refractive patterns and the air layer and has a refractive index smaller than that of the plurality of high refractive patterns.

The high refractive patterns may be spaced apart from each other by 1 μm or less.

The display device may further include a bank disposed to cover both ends of the anode electrode to define a plurality of light emitting areas, and the plurality of color filters and the plurality of high refractive patterns may overlap each of the plurality of light emitting areas.

A width of the plurality of color filters may be larger than a width of the plurality of emission areas, and a width of the plurality of high refractive patterns may be larger than a width of the plurality of color filters.

The plurality of high refractive patterns may further include a plurality of second protrusions disposed on the side surface.

Based on the same unit area, the number of the plurality of first protrusions may be greater than the number of the plurality of second protrusions.

Each of the plurality of first protrusions may have a shape whose width decreases upward.

The low refractive layer may fill space between each of the plurality of first protrusions.

The plurality of first protrusions may be disposed in a sub-wavelength grating structure on an upper surface of each of the plurality of high refractive patterns.

The display device may further include a plurality of dummy patterns disposed between a plurality of high refractive patterns.

Each of the plurality of dummy patterns may include a plurality of third protrusions disposed on an upper surface and a plurality of fourth protrusions disposed on a side surface.

A top edge of the plurality of third protrusions may be coplanar with a top edge of the plurality of first protrusions.

The plurality of dummy patterns may be spaced apart from each other with the plurality of high refractive patterns and the air layer interposed therebetween.

The interface between the low refractive layer and the air layer may be concave shaped.

A distance between the plurality of high refractive patterns and the plurality of dummy patterns may be 1 μm or less.

The display apparatus may further include a black matrix disposed between the plurality of color filters, and the plurality of dummy patterns may be disposed on the black matrix.

A refractive index of the plurality of high refractive patterns may be 1.6 or more.

A refractive index of the low refractive layer may be smaller than the refractive index of the high refractive pattern and larger than the refractive index of the air layer.

A display device according to another embodiment of the present specification includes a substrate, a plurality of light emitting elements which is disposed on the substrate and includes an anode electrode, a light emitting layer, and a cathode electrode, a plurality of color filters disposed on the plurality of light emitting elements, a plurality of high refractive patterns which correspond to each of the plurality of color filters, is disposed to be spaced apart from each other with an air layer interposed therebetween, and include a plurality of first protrusions disposed in a sub-wavelength grating structure on each upper surface thereof and a plurality of second protrusions disposed on each side in a smaller number per unit area than the plurality of first protrusions, and a low refractive layer covering the high refractive pattern and the air layer, wherein the refractive index of the high refractive pattern is greater than the refractive index of the air layer and the low refractive layer.

The display device may further include a plurality of dummy patterns disposed on the same layer as the plurality of high refractive patterns, and each of the plurality of dummy patterns may include a plurality of third protrusions disposed on an upper surface and a plurality of fourth protrusions disposed on a side surface.

Each of the plurality of dummy patterns may be disposed to be spaced apart from the plurality of high refractive patterns with the air layer interposed therebetween, between the plurality of high refractive patterns.

Each of the plurality of first protrusions and the plurality of second protrusions may have a conical shape.

According to another feature of the present specification, the refractive index of the low refractive layer may be greater than that of the air layer.

Although the exemplary embodiments of the present disclosure have been described in detail with reference to the accompanying drawings, the present disclosure is not limited thereto and may be embodied in various forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. All the technical concepts in the equivalent scope of the present disclosure should be construed as falling within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate;
a plurality of transistors on the substrate;
a plurality of light emitting elements on the plurality of transistors, the plurality of light emitting elements including an anode electrode, a light emitting layer, and a cathode electrode;
a plurality of color filters on the plurality of light emitting elements;
a plurality of high refractive patterns disposed such that each of the plurality of high refractive patterns is spaced apart from each other, such that each high refractive pattern corresponds to a respective color filter of the plurality of color filters, the plurality of high refractive patterns including a plurality of first protrusions on an upper surface of the plurality of high refractive patterns;
an air layer in an area between high refractive patterns of the plurality of high refractive patterns; and
a low refractive layer on the plurality of high refractive patterns and the air layer, the low refractive layer having a refractive index smaller than a refractive index of the plurality of high refractive patterns.

2. The display device according to claim 1, wherein each of the plurality of high refractive patterns is spaced apart from each other by 1 μm or less.

3. The display device according to claim 1, further comprising:
a bank on the anode electrode such the opposing ends of the anode electrode are covered, the bank defining a plurality of light emitting areas,
wherein the plurality of color filters and the plurality of high refractive patterns overlap each of the plurality of light emitting areas.

4. The display device according to claim 3, wherein a width of each of the plurality of color filters is larger than a width of a corresponding light emitting area of the plurality of light emitting areas, and
wherein a width of each of the plurality of high refractive patterns is larger than a width of a corresponding color filter of the plurality of color filters.

5. The display device according to claim 1, wherein each of the plurality of high refractive patterns further includes a plurality of second protrusions on a side surface of the respective high refractive pattern.

6. The display device according to claim 5, wherein based on the same unit area, a number of the plurality of first protrusions of a respective high refractive pattern is greater than a number of the plurality of second protrusions of the respective high refractive pattern.

7. The display device according to claim 1, wherein each of the plurality of first protrusions decreases in width toward a top end of the plurality of first protrusions.

8. The display device according to claim 7, wherein the plurality of first protrusions is disposed in a sub-wavelength grating structure on an upper surface of each of the plurality of high refractive patterns.

9. The display device according to claim 8, wherein a period of the plurality of first protrusions formed in the sub-wavelength grating structure is equal to or less than an optical wavelength emitted from the plurality of light emitting elements.

10. The display device according to claim 1, wherein the plurality of high refractive patterns further includes inorganic particles.

11. The display device according to claim 1, further comprising a plurality of dummy patterns, each of the plurality of dummy patterns disposed between high refractive patterns of the plurality of high refractive patterns.

12. The display device according to claim 11, wherein each of the plurality of dummy patterns includes a plurality of third protrusions on a top surface of the respective dummy pattern and a plurality of fourth protrusions on a side surface of the respective dummy pattern.

13. The display device according to claim 12, wherein a top edge of the plurality of third protrusions are coplanar with a top edge of the plurality of first protrusions.

14. The display device according to claim 11, wherein each of the plurality of dummy patterns is spaced apart from each other, such that at least one high refractive pattern of the plurality of high refractive patterns and the air layer are interposed therebetween.

15. The display device according to claim 11, wherein a distance between a high refractive pattern of the plurality of high refractive patterns and a dummy pattern of the plurality of dummy patterns is 1 μm or less.

16. The display device according to claim 11, further comprising:
a black matrix disposed between color filters of the plurality of color filters,
wherein a dummy pattern of the plurality of dummy patterns is on the black matrix.

17. The display device according to claim 1, wherein a refractive index of the plurality of high refractive patterns is 1.6 or higher.

18. The display device according to claim 1, wherein a refractive index of the low refractive layer is smaller than a refractive index of the plurality of high refractive patterns and larger than a refractive index of the air layer.

19. The display device according to claim 1, wherein the low refractive layer fills space between each of the plurality of first protrusions.

20. The display device according to claim 1, wherein an interface between the low refractive layer and the air layer is concave shaped.

21. A display device comprising:
a substrate;
a plurality of light emitting elements is on the substrate, the plurality of light emitting elements including an anode electrode, a light emitting layer, and a cathode electrode;
a plurality of color filters on the plurality of light emitting elements;
a plurality of high refractive patterns, each high refractive pattern corresponding to each of the plurality of color filters, the plurality of high refractive patterns disposed such that each of the plurality of high refractive patterns is spaced apart from each other with an air layer interposed therebetween, the plurality of high refractive patterns including a plurality of first protrusions disposed in a sub-wavelength grating structure on an upper surface of the plurality of high refractive patterns and a plurality of second protrusions on a side surface of each of the plurality of high refractive patterns in a smaller number per unit area than the plurality of first protrusions; and
a low refractive layer covering the high refractive pattern and the air layer,
wherein the high refractive pattern has a refractive index larger than the refractive index of the air layer and refractive index of the low refractive layer.

22. The display device according to claim 21, wherein a period of the plurality of first protrusions formed in the sub-wavelength grating structure is equal to or less than an optical wavelength emitted from the plurality of light emitting elements.

23. The display device according to claim 21, wherein the plurality of high refractive patterns further includes inorganic particles.

24. The display device of claim 21, further comprising:
a plurality of dummy patterns on a layer on which the plurality of high refractive patterns is disposed,
wherein each of the plurality of dummy patterns includes a plurality of third protrusions on an upper surface of the respective of dummy pattern and a plurality of fourth protrusions on a side surface of the respective dummy pattern.

25. The display device according to claim 24, wherein each of the plurality of dummy patterns is disposed between high refractive patterns of the plurality of high refractive patterns and is spaced apart from the respective high refractive patterns with an air layer interposed therebetween.

26. The display device according to claim 21, wherein the plurality of first protrusions and the plurality of second protrusions are each in a conical shape.

27. The display device according to claim 21, wherein the refractive index of the low refractive layer is greater than the refractive index of the air layer.
